(19) United States
(12) Patent Application Publication
(10) Pub. No.: US 2018/0342623 A1
(43) Pub. Date: Nov. 29, 2018

(54) HfLaO passivated zinc-oxide thin-film transistor with high field-effect mobility

(71) Applicant: Albert Chin, Santa Clara, CA (US)

(72) Inventor: Albert Chin, Santa Clara, CA (US)

(21) Appl. No.: 15/603,445

(22) Filed: May 24, 2017

(51) Int. Cl. H01L 29/786; H01L 29/04; H01L 23/31; H01L 23/29; H01L 21/56

(52) U.S. Cl. CPC H01L 29/7869; H01L 29/78603; H01L 29/04; H01L 23/3171; H01L 29/45; H01L 29/78606; H01L 29/78636; H01L 21/56; H01L 23/291

(57) ABSTRACT

Improved thin film transistor device and method, comprising transparent multi-layer thin-film transistors (TFT) disposed over a flexible polyethylene naphthalate (PEN) substrate with a nano-crystalline ZnO channel layer, and a novel HfLaO passivation layer. This device, which may be made at room temperature, has a high field-effect mobility (μ_{FE}) of 345 cm2/Vs, small sub-threshold slope (SS) of 103 mV/dec, high on-current/off-current (I_{ON}/I_{OFF}) of 7×10⁶, and a low drain-voltage (V_{D}) of 2V for low power operation. Although prior art ZnO based TFT had unimpressive performance, use of the novel HfLaO passivation layer appears to greatly improve the performance of ZnO TFT by preventing trace levels of H₂O from forming unwanted Zn—OH bonds, thus disrupting ZnO nanocrystals. At least some of the problems with prior ZnO TFT may be attributed to these Zn—OH bonds, which damage ZnO crystallinity, create charged scattering centers, and form potential barriers that degrade mobility.

### BACKGROUND OF THE INVENTION

### Field of the Invention

This invention is in the field of thin film transistors and semiconductor passivation technology.

### Description of the Related Art

Thin film transistors (TFT) are a type of field effect transistor. TFT are multi-layered devices, typically formed from thin films of active semiconductors on a supporting substrate. This substrate can be a rigid substrate, such as glass, or a flexible substrate such as Polyethylene naphthalate (PEN). Thin film transistors typically also use transparent electrodes formed from various materials such as indium tin oxide (ITO) and other materials.

The various TFT thin films can be made to be transparent, and the TFT substrate, regardless of if it is rigid or flexible, can also be transparent, thus creating a transparent device. As a result thin film transistors can be useful for various display devices such as liquid crystal displays (LCD) and the like.

High field effect mobility (μ_{F}) is considered to be a valuable TFT characteristic, and methods to improve the mobility of thin-film transistors (TFT) can lead to improved displays with higher resolution and faster response time.

TFT thin films may be formed from various types of materials. Active semiconductor TFT thin film components can be made from silicon, and other types of active semiconductors as well, such as zinc oxide (ZnO), hafnium oxide, and other materials.

In addition to substrate materials, active semiconductors and often transparent electrodes, semiconductors such as TFT can also use passivation layers. These are typically a thin coating of protective material applied to the outer layer of the TFT device to protect it against corrosion.

Various materials useful for active semiconductors, transparent materials, and passivation layers have been taught. Prior art on flexible ZnO methods includes Li, H. U. et al. “ZnO thin film transistors for more than just displays”. IEDM Tech. Dig. 523 (2015). Prior art work on flexible MoS₂ methods includes Petrone, N., Cui, X., Hone, J., Chari, T. & Shepard, K. “Flexible 2D FETs using hBN dielectrics”. IEDM Tech. Dig. 534 (2015). Prior art work on Rigid ITO/IGZO methods includes Kim, S. I. et al. “High performance oxide thin film transistors with double active layers”. IEDM Tech. Dig. 73 (2008). Prior art work on Rigid ZnON methods includes Kim, T. S. et al. “High performance gallium-zinc oxynitride thin film transistors for next-generation display applications”. IEDM Tech. Dig. 660 (2013). Prior art work on amorphous In ZnGaO (IGZO) TFT methods includes Bak, J. Y. et al. “Origin of degradation phenomenon under drain bias stress for oxide thin film transistors using IGZO and IGO channel layers”. Scientific Reports 5, 7884 (2015).

### BRIEF SUMMARY OF THE INVENTION

In some embodiments, the invention may be viewed as a solution to the problem, “Why do ZnO based TFT have generally unimpressive performance?”, or “How to produce ZnO based TFT with substantially improved performance?” The invention answers this question, and provides novel devices and methods to solve this problem.

We were initially interested in advancing the art of light weight, bendable, TFT based displays. Such displays require flexible electronics, such as flexible thin film transistors. To produce improved next generation bendable light displays, with higher pixel density, faster speeds, and lower power requires that improved flexible electronics, such as improved flexible TFT be developed. To achieve this goal, we investigated the possibility of producing improved TFT constructed from novel materials and novel material combinations.

Amorphous InZnGaO (IGZO) based TFT are one potential candidate for improved flexible electronics. IGZO based TFT have a low off-current (I_{ON}), due to the IGZO material's large energy bandgap and high mobility of overlapped s-orbitals. However, IGZO TFT are expensive because Indium (In) is a rare material, present in only limited quantities in the Earth's crust.

By contrast, Zinc Oxide (ZnO) is quite inexpensive, but no high mobility ZnO based TFT have been reported to date. The invention is based, in part, on the insight that if certain problems can be solved, crystallized ZnO based TFT may be another potential candidate for improved flexible electronics.

Polycrystalline silicon (Poli-Si) based TFT have a much higher mobility than amorphous-Si based TFTs. The invention is based, in part, on the insight that the performance of ZnO based TFT may also be substantially improved if the ZnO based TFT also used ZnO in a crystalline form, rather than in an amorphous form.

Here a high performance, nano-crystallized ZnO TFT produced using low-cost Polyethylene naphthalate (PEN) flexible substrate is disclosed. This nano-crystalline ZnO TFT is based on a flexible substrate with a high dielectric constant (high-κ) gate oxide. This TFT also uses a novel HfLaO passivation on nano-crystalline ZnO technique, producing a novel HfLaO passivation layer. This device can be produced using room temperature processing steps.

More generally, we teach an apparatus comprising a flexible or a rigid substrate layer; with at least one multi-layer thin-film transistor disposed over this substrate layer. At least one of these layers comprises a nano-crystalline zinc-oxide channel layer, or other type of crystallized metal-oxide channel layer. At least some of these layers further comprise gate layers. Further, we teach that it is important that at least one of these layers further comprise a passivation layer. This passivation layer may be HfLaO, or other material selected to prevent ambient moisture from disrupting nano-crystals in this nano-crystalline zinc-oxide channel layer.

Using our novel HfLaO passivation on nano-crystalline ZnO device and methods, we were able to produce a ZnO based TFT with a remarkably high mobility μ_{FE} of 345 cm²/Vs. This is a mobility μ_{FE} value that is even higher than IGZO and ZnON TFTs made on rigid glass, and is a record high mobility value for TFT devices based on flexible substrates as well.

The invention's novel HfLaO passivation on nano-crystalline ZnO technique appears to produce compelling advantages over prior art. For comparison, control non-passivated ZnO based TFT devices have a mobility (μ_{FE}) of only 43 cm²/Vs.

The high mobility finding is further supported by other findings, such as a low interface trap density and small SS (sub-threshold slope) of only 103 mV/dec. Additionally, a high I_{ON}/I_{OFF} (on-current/off-current) ratio of 7×10⁶, and a low V_{D} (drain-voltage) of 2 V were also measured. This shows that the invention's improved TFT can reach a low switching power of C_{G}V_{D}²f/2, where C_{G} and f are the gate capacitance and operation frequency, respectively.

To understand why these methods produced such an unexpectedly large improvement in mobility, we analyzed our devices using X-ray photoelectron spectroscopy (XPS).

We found that, relative to the HfLaO passivated ZnO TFT devices; the XPS results from the non-passivated ZnO TFT devices showed a strong OH bonding signal. Based on this discovery, we believe that our unexpectedly good results were obtained because the HfLaO passivation layer protected the crystalline forms of ZnO from being degraded into an amorphous form.

In particular, we believe that moisture absorption breaks the Zn—O bonding in ZnO crystals, producing HO—Zn—OH (Zn(OH)₂) compounds. These HO—Zn—OH compounds may form dangling bonds and charged scattering centers that strongly lower the mobility of the ZnO TFT.

It appears that for passivation purposes, LaO-based dielectrics (such as HfLaO) may be superior to other passivation techniques. This is because, according to the XPS data, LaO dielectrics reduce moisture absorption, and thus producing a lower amount of the unwanted HO—Zn—OH compounds.

Although our interests were more focused on flexible support substrates, such as PEN, the remarkably high μ_{FE} of our HfLaO/ZnO TFT devices suggests that this technique may be useful for both flexible and rigid display applications, as well as other types of electronic devices as well.

### BRIEF DESCRIPTION OF THE DRAWINGS

FIG. 1 shows a photograph of a bendable electronic device fabricated from TFTs on a flexible PEN substrate.

FIG. 2 shows the I_{DS}-V_{DS} and characteristics of ZnO/high-κ/TaN TFT on flexible PEN without (a) and with (b) HfLaO passivation. FIG. 2 also shows the I_{DS}-V_{GS} characteristics of ZnO/high-κ/TaN TFT on flexible PEN without and with HfLaO passivation (c).

FIG. 3 shows the μ_{FE}-V_{GS} characteristics of ZnO/high-κ/TaN TFT on flexible PEN both without and with HfLaO passivation.

FIG. 4 shows: (a) SIMS depth profile of various layers of ZnO on HfO₂/TiO₂/SiO₂ stacked gate dielectrics, (b) a cross-sectional transmission electron microscope (TEM) photograph showing some of the various layers, and (c) XRD spectra of the same ZnO/high-κ/TaN structure on a flexible PEN substrate.

FIG. 5 shows the XPS spectra of a ZnO/high-κ/TaN layered structure on flexible PEN substrate (a) without and (b) with HfLaO passivation. Here the passivated HfLaO passivation layer was removed for the XPS measurement.

FIG. 6 shows a schematic of the ZnO/high-κ/TaN energy bands and the nano-crystalline-ZnO band structures on flexible PEN without (left) and with (right) a HfLaO-passivation layer.

### DETAILED DESCRIPTION OF THE INVENTION

As previously discussed, the invention may be viewed as a solution to the problem, “Why do ZnO based TFT have generally unimpressive performance?”, or “How to produce ZnO based TFT with substantially improved performance?”

As will be described in more detail shortly, in one embodiment, the invention may be an apparatus (e.g. an electronic apparatus) comprising: a flexible (e.g. PEN) or a rigid (e.g. glass) substrate layer, with at least one multi-layer thin-film transistor disposed over this substrate layer. At least one of these layers will comprise a nano-crystalline zinc-oxide metal-oxide channel layer. In some embodiments, other types of metal oxide channel layers may also be used. At least some of these layers will further comprise gate layers. In a particularly favored embodiment, at least one of these layers will further comprise an HfLaO passivation layer selected to prevent ambient moisture from disrupting nano-crystals in the nano-crystalline zinc-oxide channel layer. Alternatively other types of materials (which can include other types of LaO materials) selected to prevent ambient moisture from disrupting nano-crystals in the nano-crystalline zinc-oxide channel layer may also be used.

In some embodiments, which are particularly useful for display devices, the substrate layer may be an optically clear material, and the apparatus may be transparent. If a flexible substrate layer is desired (for example to produce a flexible device, such as a flexible display device), the flexible substrate layer can comprise a flexible polyethylene naphthalate substrate.

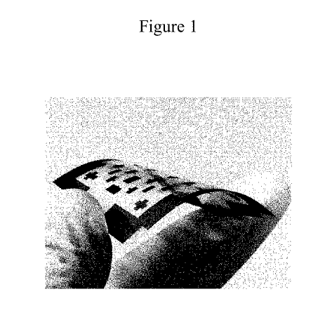

FIG. 1 shows a photo of the flexible TFT devices fabricated on a flexible PEN substrate.

In some embodiments, the gate layers can further comprise a high dielectric constant gate oxide stack comprising HfO₂, TiO₂, and SiO₂ or other high-dielectric constant material layers. Alternatively or additionally, the gate layers can further comprise a metal-gate, such as a metal gate layer (such as a tantalum nitride gate material), layers comprising a high dielectric constant gate (which itself can be a high dielectric constant gate oxide stack comprising HfO₂, TiO₂, and SiO₂ layers), and a layer comprising source/drain electrodes such as aluminum source/drain electrodes.

In some embodiments, the apparatus will further comprise a smoothing layer disposed over this flexible substrate layer. Here at least one multi-layer thin film transistor is typically disposed over this smoothing layer.

As will be discussed in more detail, an important aspect of the invention is that the nano-crystalline zinc-oxide (or other crystallized metal-oxide) channel layer be further selected or treated so as to be substantially free from HO—Zn—OH (e.g. Zn(OH)₂) compounds that disrupt nano-crystals in these nano-crystalline zinc-oxide (or other crystallized metal-oxide) layers. As will be discussed, one good way to accomplish this is to use the passivation techniques disclosed herein to help prevent formation of such Zn(OH₂) compounds.

Alternatively, the invention may also comprise a method of improving the high field-effect mobility characteristics of a thin-film transistor. This method may comprise forming a multi-layer thin-film transistor by depositing at least one nano-crystalline zinc-oxide thin film transistor channel layer over a support comprising a substrate layer. In a preferred embodiment, the method will also comprise depositing at least one passivation layer, such as an HfLaO passivation layer, over this support so that the nano-crystalline zinc-oxide channel layer is disposed between the support and this at least one passivation layer.

For example, the method can further comprise preventing ambient moisture from disrupting nano-crystals in the nano-crystalline zinc-oxide channel layer. This can be done by using (e.g. applying to the device) at least one passivation layer comprising a material (e.g. HfLaO, LaO) and/or other material selected to prevent ambient moisture from disrupting nano-crystals in the nano-crystalline zinc-oxide channel layer.

A high capacitance density of 0.35 μF/cm² was measured that lead to an equivalent-oxide-thickness (EOT) of 9.9 nm. A still low leakage current of 1.4×10⁻⁵ A/cm² was measured at 1.5 V, even when the devices were processed at room temperature. These results show the merits of the high-κ dielectrics, especially the higher κ TiO₂ dielectric. The TiO₂ has a higher κ value for low voltage operation. To improve the interface, extra SiO₂ dielectric was inserted between ZnO and TiO2. To improve the leakage current via the low conduction band offset (ΔE_{C}) of TiO₂, stacked TiO₂/HfO₂ was applied.

In general, high dielectric constant gate oxide materials can include HfO₂, ZrO₂, Al₂O₃, La₂O₃ and their mixed ternary or quaternary compounds. A preferred high dielectric constant typically ranges from about 20 to 100.

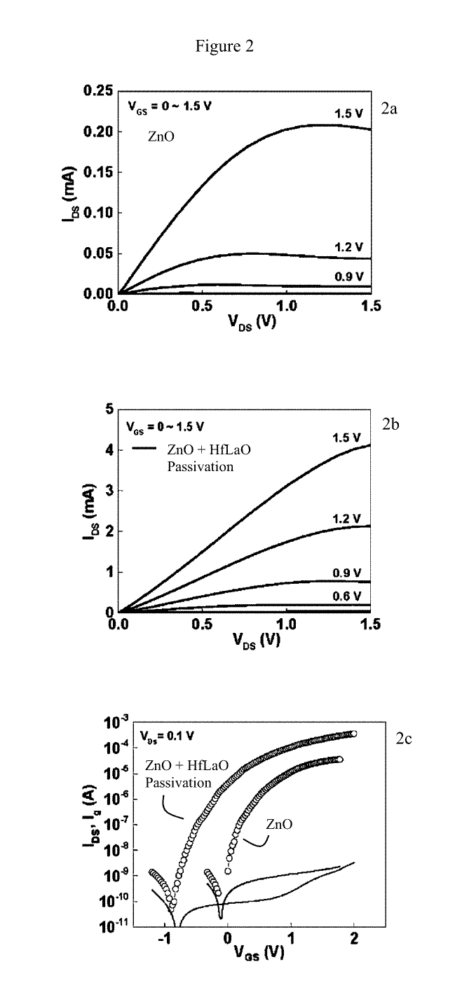

FIG. 2(a), FIG. 2(b) and FIG. 2(c) show the transistor's drain-source current versus drain-source voltage (I_{DS}−V_{DS}), and I_{DS} versus gate-source voltage (I_{DS}−V_{GS}) characteristics of ZnO/high-κ/metal-gate TFTs both with and without HfLaO passivation. The ZnO TFTs without passivation show reasonable performance of I_{ON}/I_{OFF} of 2×10⁵, SS of 112 mV/dec, and a V_{T} of 0.78 V. Here the gate leakage current is lower than I_{OFF} due to the thick stacked gate dielectric.

After HfLaO passivation, the ZnO TFTs show more than an order of magnitude higher I_{ON} and 4 times lower I_{OFF}, with a large I_{ON}/I_{OFF} of 7×10⁶, a small SS of 103 mV/dec, and a low V_{T} of 0.13 V. This good device performance was achieved at a low VD of 2V. This low voltage is crucial because it lowers the switching power by orders of magnitude relative to prior art TFT devices. Additionally, the steep SS means that the transistors can be turned on faster for lower voltage and power operation

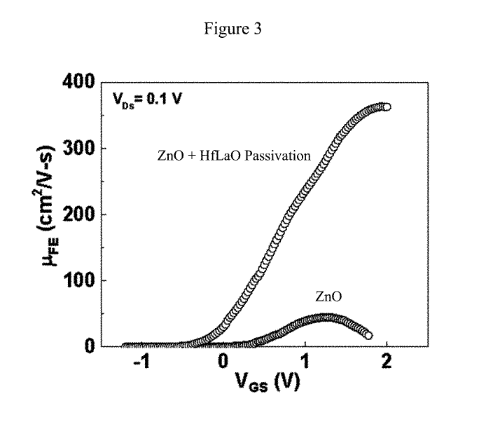

The μ_{EF}-V_{GS} characteristics, obtained from the measured I_{DS}-V_{GS} characteristics, are shown in FIG. 3. For control non-passivated devices, a relatively low peak μ_{FE} of 43 cm²/Vs is obtained for room-temperature-processed ZnO TFT.

By contrast, after HfLaO passivation, the invention's improved TFT devices produced a remarkably high mobility μ_{FE} value of 345 cm²/Vs. This is the highest mobility value for TFT on flexible substrate that has been observed to date, and is even higher than the reported mobility values for IGZO and ZnON TFTs fabricated on rigid substrates.

Note that the much improved mobility μ_{FE} for HfLaO-passivated devices are due to the higher I_{ON} and the lower I_{OFF} values.

It is important to notice that the μ_{FE value} increases monotonically with increasing gate length:

$${μ}_{FE} \approx {μ}_{0} \frac{L}{L + {μ}_{0} {WC}_{oX} {R}_{SD} ( {V}_{GS} - {V}_{th} )} \qquad ( 1 )$$

Here R_{SD} is the source/drain series resistance, L is the gate length, μ_{FE} is the apparent field-effect mobility and μ₀ is the true field effect mobility. At long gate lengths, the value of μ_{FE} approaches that of μ₀; thus, for better performance, a relatively long gate length (48 μm gate length) was used.

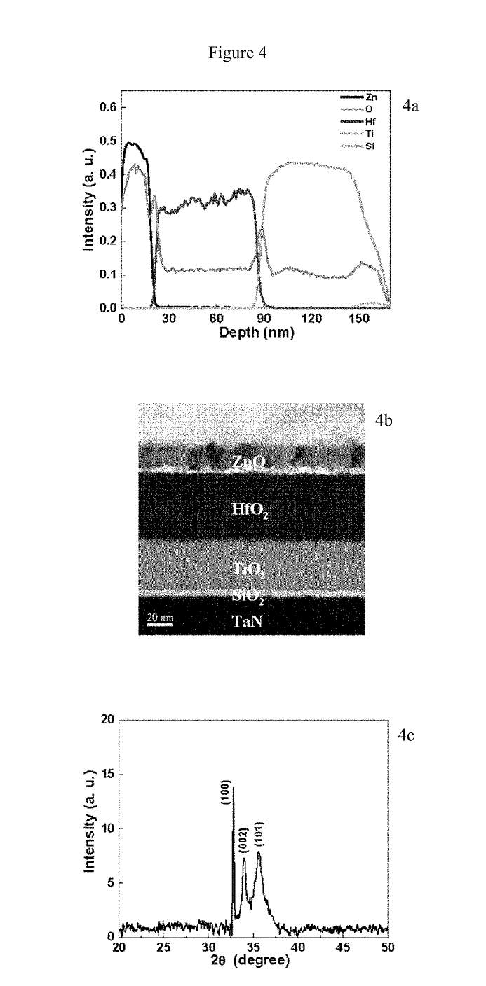

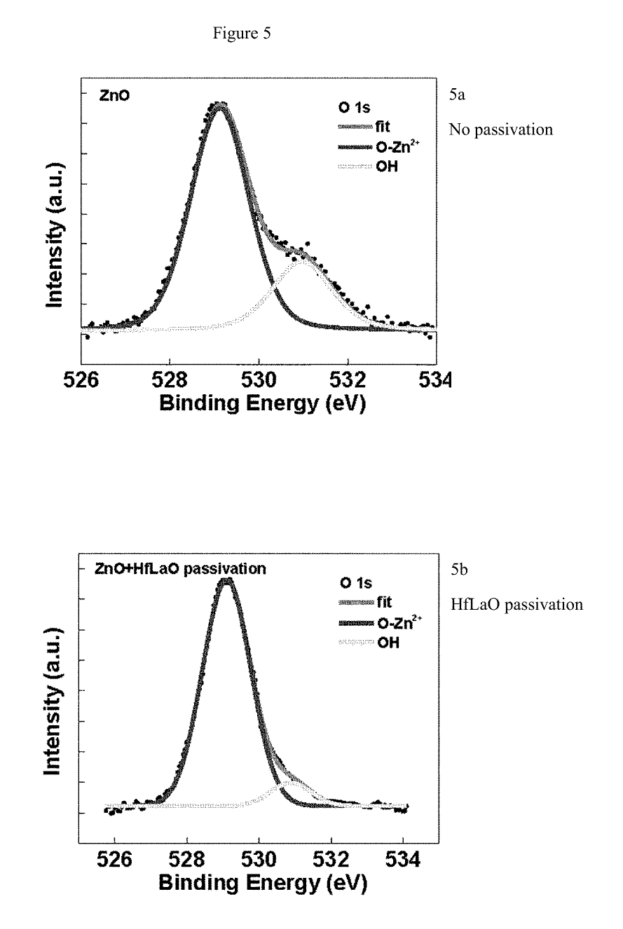

How can HfLaO passivation produce such an unexpectedly large improvement in mobility? To better understand this effect, the material and structure of the various devices were analyzed in more detail. These results are shown in FIGS. 4 and 5.

FIG. 4(a) shows a secondary ion mass spectrometry (SIMS) depth profile of a ZnO channel, HfO2, TiO₂, and thin SiO₂ gate dielectric stack, showing that all layers can be recognized. The device structure layers of Al contact, ZnO channel, high-K gate dielectric stack, and TaN (tantalum nitride) metal-gate were also observable from the cross-sectional transmission electron microscopy (TEM) image shown in FIG. 4(b).

The results show that the ZnO active layer forms a columnar nano-crystalline structure with an average crystal structure size of ˜10-20 nm. The formed crystalline nature of this structure is further revealed in the X-ray diffraction (XRD) spectra shown in FIG. 4(c). Even though the ZnO in this active layer was deposited by sputtering at room temperature (and thus might be expected to have a more amorphous X-ray diffraction structure), highly oriented phases of XRD peaks, indicating a nano-crystalline structure, were measured.

Note that although we use the term nano-crystalline to refer to ZnO and other nano-crystalline metal oxides, the alternative term “polycrystalline” metal-oxide may also be used. Often a preferred nano-crystalline or poly-crystalline grain size for such materials is between 1 nm to 300 nm

The full-width at half-maximum (FWHM) X-ray diffraction patterns revealed by the XRD spectra are comparable with the data of ZnO published in literature (e.g. Chen, R. et al. “Self-aligned top-gate InGaZnO thin film transistors using SiO₂/A₁₂O₃ stack gate dielectric”. Thin Solid Films 548, 572 (2013); Im, S., Jin, B. J. & Yi, S. “Ultraviolet emission and microstructural evolution in pulsed-laser-deposited ZnO films”. J. Appl. Phys. 87, 9 (2000). By contrast, IGZO layers, under XRD, exhibit an amorphous structure.

FIG. 5(a) and FIG. 5(b) compare the XPS spectra obtained from TFT devices respectively produced without (5a) and with (5b) HfLaO passivation. The atomic composition of the nano-crystalline structure is identified to be Zn²⁺—O²⁻, as measured from the XPS spectra. Note that a significant amount of OH bonding signal obtained from the non-passivated device (5a), which was much higher than the amount of OH bonding signal obtained from the HfLaO passivated device (5b).

Even though dry process steps were used to fabricate the devices, the OH bonding in nano-crystalline ZnO appears to have originated by the device's absorption of small amounts of residual moisture from the dry ambient air used in the manufacturing process.

The chemical reaction of ZnO and H₂O is expressed as:

ZnO+H₂O→Zn(OH)₂ (2)

Water (H₂O) molecules are relatively small, and in addition to reacting with surface ZnO, can also penetrate into the depths of the thin (20-nm) ZnO layer and react with ZnO nanocrystal grain boundaries through this layer. These grain boundaries have a high defect density, and thus are highly reactive with H₂O.

Once Zn(OH)₂ is formed, it further damages the Zn—O bonded nano-crystals, and creates dangling bonds. These dangling bonds also form charged states in the ZnO bandgap.

Changes in the XPS OH signal, and related charge defects, are also supported from the high positive charge density (ΔQₚ) of 2×10¹² cm⁻². This was obtained from the V_{T} shift (ΔV_{T}) between the HfLaO-passivated and non-passivated ZnO devices shown in FIG. 3(b); and from the formula ΔQₚ=C_{G}×ΔV_{T}

Such positive charge and dangling bond effects have been seen before for other materials. For example, these positive charges and dangling bonds are also found in the interim SiOₓ region between SiO₂ layers and the Silicon (Si) body/support/substrate.

On the other hand, in the HfLaO passivated device shown in FIG. 5b, the XPS spectra OH bonding signal is much lowered, relative to the non-passivated device shown in FIG. 5a. However high-κ gate dielectrics, such as La₂O₃, can also absorb moisture, which in turn can also reduce amount of Zn(OH)₂ formation.

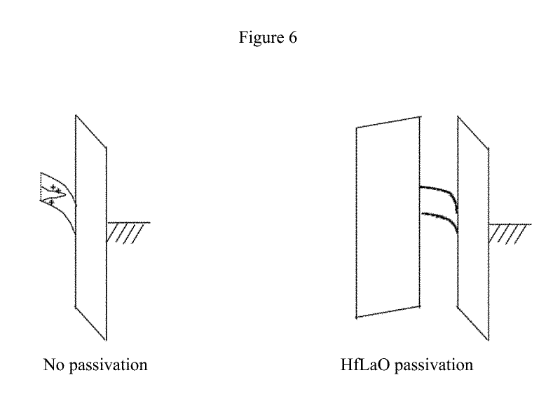

In terms of the solid state physics of the situation, we believe that the high-density positive ΔQₚ further causes the Fermi-level to come closer to the valance band. As shown in the schematic diagrams of FIG. 6, the positive charge in the surface and the raised surface potential can also increase the ZnO depletion region, and lower the n-type ZnO conduction.

FIG. 6 shows that because the invention's improved HfLaO “proper” passivation blocks the reaction between H₂O and ZnO, the OH bonding related charges in HfLaO/ZnO are much reduced. This in turn reduces the potential barriers at both surface and grain boundaries, which in succession leads to much higher mobility, because the nano-crystalline form of ZnO has overlapped s-orbitals for conduction.

More specifically, FIG. 6 is inferred from the measured Id-Vg results; the non-passivated device showed a positive Vt shift, which is related to positive charge in the ZnO because both passivated and non-passivated devices were made at the same time. The positive charges raised the Fermi-level to deplete the ZnO, and create potential barriers at the nano-crystalline or poly-crystalline grain boundaries, which in turn leads to lower mobility. In FIG. 6, the various parallelograms can be viewed as representing these nano-crystalline or polycrystalline grains.

In a MOSFET type device, the electron wave-function typically distributes over about 20 nm. Therefore the high-density ΔQₚ will also increase electron scattering rates, and decrease mobility. However, the passivation does not affect the gate equivalent-oxide-thickness (EOT), because the EOT of a TFT only counts the dielectric next to the gate.

The improved passivation techniques disclosed herein can really be viewed as teaching “proper passivation” for this type of system. Proper passivation blocks the reaction between H₂O and ZnO. As a result, the amount of OH bonding in HfLaO/ZnO materials is much reduced. This lowers the ΔQₚ and the potential barriers at the ZnO grain boundaries. The net result of the invention's improved passivation techniques is a much higher mobility. From a physics perspective, this is because the nano-crystalline form of ZnO has overlapped s-orbitals that improve conduction

Table 1 compares the device performance of various materials deposited on both flexible and rigid substrates. Here the prior art values with ZnO, MoS₂ on flexible substrates was taken from Li, H. U. et al. “ZnO thin film transistors for more than just displays”. IEDM Tech. Dig. 523 (2015); and Petrone, N., Cui, X., Hone, J., Chari, T. & Shepard, K. “Flexible 2D FETs using hBN dielectrics”. IEDM Tech. Dig. 534 (2015) is shown.

The prior art values obtained with IGZO and ZnON TFTs on rigid glass substrates was taken from Kim, S. I. et al. “High performance oxide thin film transistors with double active layers”. IEDM Tech. Dig. 73 (2008); and Kim, T. S. et al. “High performance gallium-zinc oxynitride thin film transistors for next-generation display applications”. IEDM Tech. Dig. 660 (2013); are also shown for comparison.

The values obtained with the invention's HfLaO-passivated ZnO TFTs are shown in the last row.

TABLE 1

| | | | | | | Operating |
|---|---|---|---|---|---|---|
| Channel | Channel layer | Gate Insulator | SS | μ_{EF} | | Voltage |
| Materials | thickness (nm) | Materials | (V/decade) | (cm²/V · s) | I_{ON}/I_{OFF} | (V) |
| Flexible ZnO-Li-H.U. | 10 | Al2O3 | — | ~32 | ~10⁸ | 8 |
| Flexible MoS2- | ~2.6 | hBN | — | ~40 | >10⁴ | 80 |
| Petrone N. | | | | | | |
| Rigid ITO/IGZO- | 5/70 | SiO₂ | ~0.25 | 104 | >10⁷ | 15 |
| Kim S.I | | | | | | |
| Rigid ZnON-Kim T.S. | 50 | SiNₓ/SiO₂ | 0.8 | ~115 | >10⁶ | 20 |
| Flexible (This Work) | 20 | HfO₂/TiO₂/SiO₂ | 0.103 | 345 | 7 × 10⁶ | 2 |

As is shown in Table 1 (last row), the invention's mobility (μ_{EF}) value of 345, obtained for the invention's HfLaO-passivated ZnO TFT, is substantially higher than the IGZO and ZnON TFTs on rigid substrates. The invention also produces a record for the highest mobility obtained to date for flexible substrate TFTs.

Without wishing to be bound by any theory, we believe that this high mobility is possible because poly-crystalline materials typically have better material qualities and higher mobility than corresponding amorphous materials. Indeed the mobility improvement can be as large as ˜100 times higher for poly-Si TFT, as opposed to amorphous-Si TFTs. In addition to very high mobility, the HfLaO passivated ZnO TFT has many other excellent properties, such as an excellent SS, large I_{ON}/I_{OFF} and low V_{D}. This in turn enables improved devices that use less DC and AC power.

The invention thus enables improved nano-crystalline ZnO devices, such as TFT devices, that are both simple and inexpensive to manufacture. An important aspect is the invention's techniques for using improved (or “proper”) passivation to reduce the problem of OH bonding, thus reducing the problem of related charge traps and grain boundary potential barriers. Applications for this invention include improved next generation displays, and also more exotic technologies such as high-speed 3D integrated circuits, such as 3D brain-mimicking chips.

Methods

Bottom-gate ZnO/high-κ/metal-gate TFTs were made on a flexible polyethylene naphthalate (PEN) substrate. In addition to low cost, such PEN substrates have other good properties, such as a low linear thermal expansion coefficient, surface smoothness, and optical clarity.

To produce the TFT devices discussed here, a 300-nm smoothing SiO₂ layer was first deposited on the PEN substrate. Then various layers such as 60-nm TaN gate metal, tri-layer gate dielectrics of 50-nm HfO₂, 40-nm TiO₂, a 4-nm-SiO₂, and a 20-nm ZnO active layer were deposited using a physical vapor deposition (PVD) process. Then the Al source/drain (S/D) electrodes were formed. Finally, the device was passivated by depositing a 20 nm thick HfLaO dielectric with an opened S/D probing window for more convenient analysis.

Note that in FIG. 4b, which was designed to allow the ZnO layer to be more easily analyzed, the PEN and 300-nm SiO₂ layers are not shown, and the order of the layers is TaN, SiO₂, TiO₂, HFO₂, and ZnO. The passivation layer is also not shown.
The TaN gate electrode was deposited by sputtering the TaN layer using a power of 800 W, Ar/N₂ of 100/10 sccm, and a pressure of 3×10⁻³ torr.
The gate dielectric stacks were deposited by electron-gun evaporation at 5 KV, and the deposition rates were 0.24/0.2/0.1 Å/sec, respectively.
The ZnO channel was deposited by sputtering at a power of 300 W, Ar/O₂ of 20/5 sccm, and 1 Å/sec deposition rate.
The Al source-drain was deposited by thermal evaporation deposition.
The HfLaO passivation layer (not shown) was deposited by electron-gun evaporation at a deposition rate of 0.15 Å/sec. Before deposition, the chambers were pumped down to 3×10⁻⁶ torr.

We have found that the deposition rates used here was important in order to obtain good quality results. No post-deposition annealing was used. The gate size of the fabricated TFT produced in this study was 48-μm×505-μm.

To investigate the device's mobility and other material properties, X-ray diffraction (XRD), secondary ion mass spectrometry (SIMS), cross-sectional transmission electron microscopy (TEM), and X-ray photoelectron spectroscopy (XPS) analysis was done.

Due to the thin 20 nm HfLaO passivation layer, in the XPS measurement, a very low etching rate of 0.2 Å/sec was used.

1. An apparatus comprising:
a flexible or a rigid substrate layer;
at least one multi-layer thin-film transistor disposed over said substrate layer, at least one of said layers comprising a nano-crystaline zinc-oxide or other metal-oxide channel layer;
at least some of said layers further comprising gate layers; and
at least one of said layers further comprising a passivation layer selected from any of HfLaO or other material selected to prevent ambient moisture from disrupting nano-crystals in said nano-crystalline zinc-oxide channel layer.

2. The apparatus of claim 1, wherein said nano-crystalline zinc-oxide or other metal-oxide channel layer is further selected to be substantially free from HO—Zn—OH compounds that disrupt nano-crystals in said nano-crystalline zinc-oxide layers.

3. The apparatus of claim 1, wherein said gate layers further comprises a high dielectric constant gate oxide stack comprising HfO₂, TiO₂, and SiO₂ or other high-dielectric constant material layers.

4. The apparatus of claim 1, wherein said gate layers further comprise a metal-gate, said metal gate comprising a metal gate layer, layers comprising a high dielectric constant gate, and a layer comprising source/drain electrodes.

5. The apparatus of claim 4, wherein said high dielectric constant gate comprises a high dielectric constant gate oxide stack comprising HfO₂, TiO₂, and SiO₂ layers.

6. The apparatus of claim 4, wherein said metal gate layer comprises a TaN gate metal, and said source drain electrodes comprise aluminum source/drain electrodes.

7. The apparatus of claim 1, wherein said apparatus further comprises a smoothing layer disposed over said flexible substrate layer, and wherein said at least one multi-layer thin film transistor is disposed over said smoothing layer.

8. The apparatus of claim 7, wherein said smoothing layer comprises a SiO₂ layer.

9. The apparatus of claim 1, wherein said apparatus is transparent; and said substrate layer is an optically clear material.

10. The apparatus of claim 1, wherein said flexible substrate layer comprises a flexible polyethylene naphthalate substrate.

11. A substantially transparent apparatus comprising:
An optically clear flexible substrate layer;
at least one multi-layer thin-film transistor disposed over said flexible substrate layer, at least one of said layers comprising a nano-crystalline zinc-oxide channel layer;
at least some of said layers further comprising gate layers, said gate layers comprising a metal gate layer, layers comprising a high dielectric constant gate, and a layer comprising source/drain electrodes; and
at least one of said layers further comprising a HfLaO passivation layer.

12. The apparatus of claim 11, wherein said nano-crystalline zinc-oxide channel layer is further selected to be substantially free from HO—Zn—OH compounds that disrupt nano-crystals in said nano-crystalline zinc-oxide layers.

13. The apparatus of claim 11, wherein said gate layers further comprises a high dielectric constant gate oxide stack comprising HfO₂, TiO₂, and SiO₂ layers.

14. The apparatus of claim 11, wherein said metal gate layer comprises a TaN or other gate metal, and said source drain electrodes comprise aluminum source/drain electrodes.

15. The apparatus of claim 11, wherein said apparatus further comprises a smoothing layer disposed over said flexible substrate layer, and wherein said at least one multi-layer thin film transistor is disposed over said smoothing layer.

16. The apparatus of claim 15, wherein said smoothing layer comprises a SiO₂ layer.

17. The apparatus of claim 11, wherein said flexible substrate layer comprises a flexible polyethylene naphthalate or other organic substrate.

18. A method of improving high field-effect mobility characteristics of a thin-film transistor, said method comprising:
forming a multi-layer thin-film transistor by depositing at least one nano-crystalline zinc-oxide thin film transistor channel layer over a support comprising a substrate layer; and
depositing at least one passivation layer over said support so that said nano-crystalline zinc-oxide channel layer is disposed between said support and said at least one passivation layer.

19. The method of claim 18, wherein said at least one passivation layer comprises HfLaO.

20. The method of claim 18, wherein said method further comprises preventing ambient moisture from disrupting nano-crystals in said nano-crystalline zinc-oxide channel layer; and
wherein said at least one passivation layer comprises a material selected to prevent ambient moisture from disrupting nano-crystals in said nano-crystalline zinc-oxide channel layer.
